(19) United States
(12) Patent Application Publication
(10) Pub. No.: US 2025/0310666 A1
(43) Pub. Date: Oct. 2, 2025

(54) CONVERSION APPARATUS, SYSTEM, MOVING OBJECT, AND EQUIPMENT

(71) Applicant: CANON KABUSHIKI KAISHA, Tokyo (JP)

(72) Inventors: WATARU ENDO, Tokyo (JP); YASUHARU OTA, Tokyo (JP)

(21) Appl. No.: 19/087,309

(22) Filed: Mar. 21, 2025

(30) Foreign Application Priority Data
Mar. 26, 2024 (JP) 2024-049499

(51) Int. Cl. H04N 25/773; H10F 39/00

(52) U.S. Cl. CPC H04N 25/773; H10F 39/80373; H10F 39/80377

(57) ABSTRACT

Provided is a conversion apparatus including a pixel including an avalanche diode and a circuit configured to process a signal according to an output of the avalanche diode, and an output unit configured to output data according to an output signal of the pixel, in which the output unit includes a first circuit and a second circuit configured to operate at a speed faster than a speed of the first circuit, and an absolute value of a threshold voltage of a first transistor which constitutes the first circuit is larger than an absolute value of a threshold voltage of a second transistor which constitutes the second circuit.

### BACKGROUND

### Technical Field

The aspect of the embodiments relates to a conversion apparatus, a system, a moving object, and an equipment.

### Description of the Related Art

A single photon avalanche diode (SPAD) has been developed as a detector capable of detecting weak light at a single photon level. The SPAD is configured to amplify signal charges excited by a photon by approximately several to several million times using an avalanche multiplication phenomenon caused by a strong electric field induced at a p-n junction in a semiconductor. By converting currents generated by the avalanche multiplication phenomenon into pulse signals and counting the number of pulse signals, it becomes possible to directly measure the number of incident photons. Japanese Patent Laid-Open No. 2019-158806 describes a photoelectric conversion apparatus obtained by arranging pixels including avalanche photodiodes in a two-dimensional array.

Various functional blocks included in a photoelectric conversion apparatus such as an image sensor using the SPAD demand their characteristics according to respective functions, but device design according to the characteristic of each of the functional blocks has not been carried out so far. For this reason, reduction in power consumption in the photoelectric conversion apparatus using the SPAD has not been necessarily sufficient.

### SUMMARY

According to an aspect of the embodiments, there is provided a conversion apparatus including a pixel including an avalanche diode and a circuit configured to process a signal according to an output of the avalanche diode, and an output unit configured to output data according to an output signal of the pixel, in which the output unit includes a first circuit and a second circuit configured to operate at a speed faster than a speed of the first circuit, and an absolute value of a threshold voltage of a first transistor which constitutes the first circuit is larger than an absolute value of a threshold voltage of a second transistor which constitutes the second circuit.

Further features of the disclosure will become apparent from the following description of exemplary embodiments with reference to the attached drawings.

### BRIEF DESCRIPTION OF THE DRAWINGS

FIG. 1 is a block diagram illustrating a schematic configuration of a photoelectric conversion apparatus according to a first embodiment of the disclosure.

FIG. 2 is a block diagram illustrating a schematic configuration of the photoelectric conversion apparatus according to the first embodiment of the disclosure.

FIG. 3 is a block diagram illustrating a configuration example of a pixel in the photoelectric conversion apparatus according to the first embodiment of the disclosure.

FIG. 4 is a perspective view illustrating a configuration example of the photoelectric conversion apparatus according to the first embodiment of the disclosure.

FIGS. 5A to 5C are explanatory diagrams for describing a basic operation of a photoelectric conversion unit in the photoelectric conversion apparatus according to the first embodiment of the disclosure.

FIG. 6 illustrates an outline of connection between a pixel section and an image signal output section in the photoelectric conversion apparatus according to the first embodiment of the disclosure.

FIGS. 7A to 7F are explanatory diagrams for describing a method of controlling a threshold voltage of a MOS transistor.

FIG. 8 illustrates an outline of the connection between the pixel section and the image signal output section in the photoelectric conversion apparatus according to a second embodiment of the disclosure.

FIGS. 9A and 9B are explanatory diagrams for describing an operation of the photoelectric conversion unit in the photoelectric conversion apparatus according to the second embodiment of the disclosure.

FIG. 10 illustrates an outline of the connection between the pixel section and the image signal output section in the photoelectric conversion apparatus according to a third embodiment of the disclosure.

FIGS. 11A to 11C are schematic drawings for describing an equipment according to a fourth embodiment.

### DESCRIPTION OF THE EMBODIMENTS

A configuration of each of embodiments will be described with reference to the drawings. In each of the embodiments described below, an image sensing apparatus will be mainly described as an example of a photoelectric conversion apparatus. It is however noted that each of the embodiments is not limited to the image sensing apparatus and is also applicable to other examples of the photoelectric conversion apparatus. The other examples include a distance measuring apparatus (apparatus for distance measurement or the like using focus detection or time of flight (TOF)) and a light metering apparatus (apparatus for measurement of an incident light quantity or the like), for example.

In addition, a conductivity type of a semiconductor region or a well and a dopant to be implanted which will be described in the following embodiments are examples and are not limited to only the conductivity type and the dopant described in the embodiments. The conductivity type and the dopant described in the embodiments can be appropriately changed, and along with this change, a potential in the semiconductor region or the well is appropriately changed.

It is noted that a conductivity type of a transistor which will be described in the following embodiments is an example and is not limited to only the conductivity type described in the embodiments. With respect to the conductivity described in the embodiments, the conductivity type can be appropriately changed, and along with this change, a potential at a gate, a source, or a drain of the transistor is appropriately changed.

For example, in the case of a transistor caused to operate as a switch, a low level and a high level of the potential supplied to the gate may be reversed with respect to the description in the embodiments along with the change of the conductivity type. In addition, a conductivity type of a semiconductor region described in the following embodiments is also an example and is not limited to only the conductivity type described in the embodiments. With respect to the conductivity described in the embodiments, the conductivity type can be appropriately changed, and along with this change, a potential in a semiconductor region is appropriately changed.

In addition, in the following embodiments, connection between mutual elements in a circuit may be described. In this case, even when another element exists between the elements of interest, unless otherwise specified, the mutual elements of interest are treated as being connected to each other. For example, a case is considered where an element A is connected to one node of a capacitor element C including a plurality of nodes, and an element B is connected to the other node. In such a case too, unless otherwise specified, the element A and the element B are treated as being connected to each other.

A metallic member such as a wiring or a pad described in the present specification may be made of an elemental metal of one certain element or made of a mixture (alloy). For example, a wiring described as a copper wiring may be made of copper as an element or may have a composition which mainly contains copper and further contains other ingredients. In addition, for example, a pad connected to an external terminal may be made of aluminum as an element or may have a composition which mainly contains aluminum and further contains other ingredients. The copper wiring and the aluminum pad illustrated herein are examples and can be changed to be made of various metals.

In addition, the wiring and the pad illustrated herein are examples of metallic members to be used in the photoelectric conversion apparatus and may also be applicable to other metallic members.

### First Embodiment

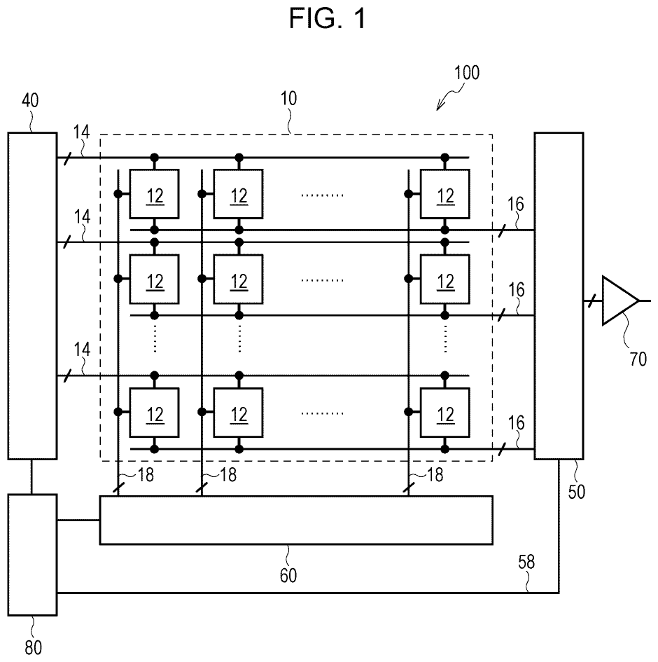

A photoelectric conversion apparatus according to a first embodiment of the disclosure will be described with reference to FIG. 1 to FIGS. 7A to 7F.

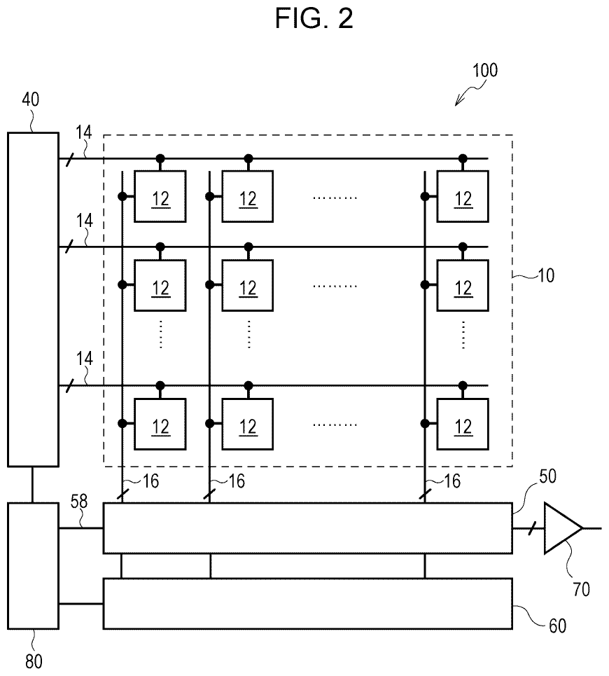

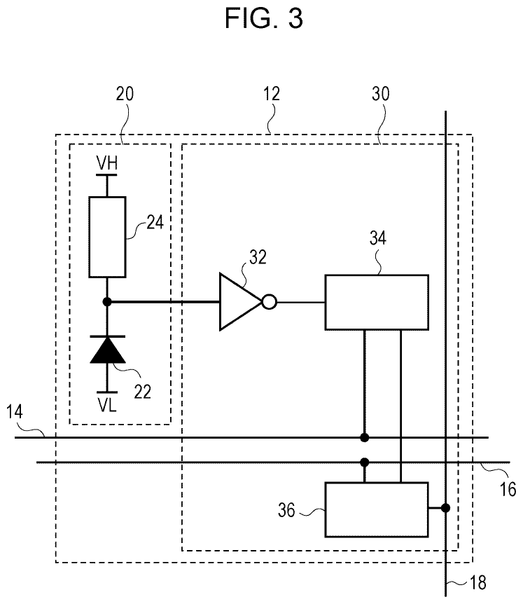

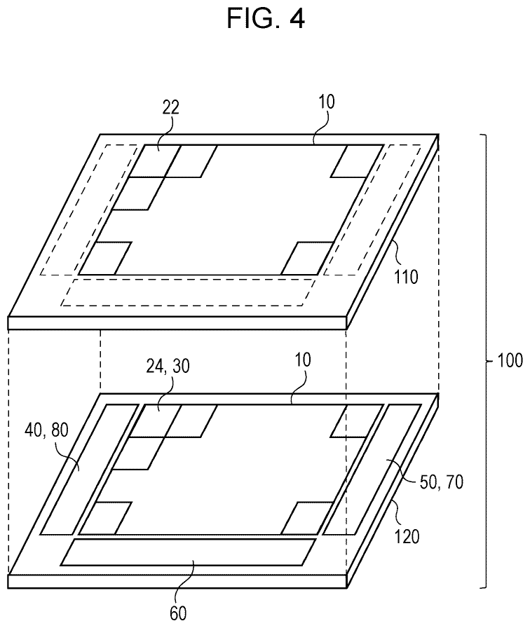

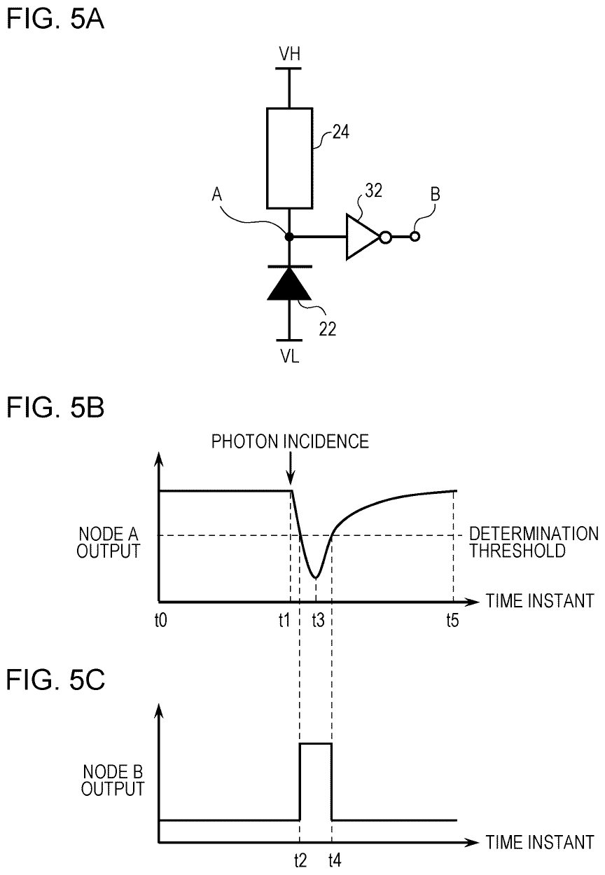

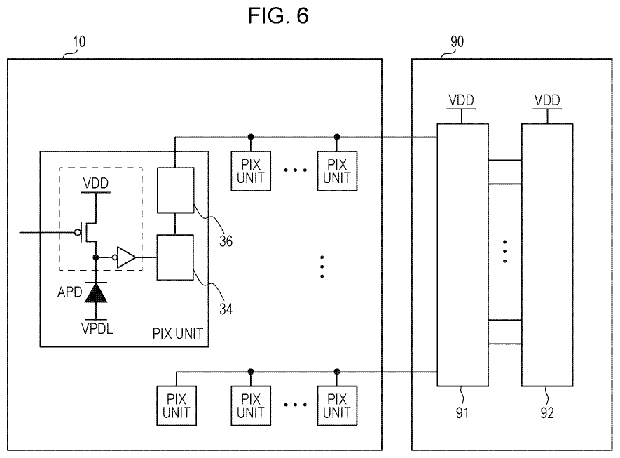

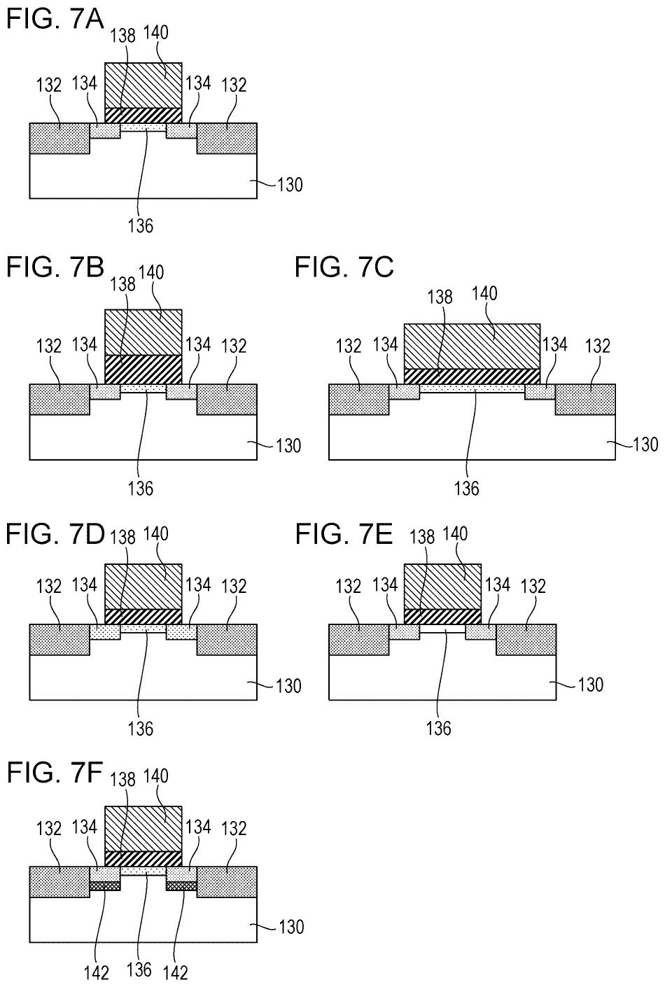

FIG. 1 and FIG. 2 are block diagrams illustrating a schematic configuration of the photoelectric conversion apparatus according to the present embodiment. FIG. 3 is a block diagram illustrating a configuration example of a pixel in the photoelectric conversion apparatus according to the present embodiment. FIG. 4 is a perspective view illustrating a configuration example of the photoelectric conversion apparatus according to the present embodiment. FIGS. 5A to 5C are explanatory diagrams for describing a basic operation of a photoelectric conversion unit in the photoelectric conversion apparatus according to the present embodiment. FIG. 6 illustrates an outline of connection between a pixel section and a readout circuit unit in the photoelectric conversion apparatus according to the present embodiment. FIGS. 7A to 7F are explanatory diagrams for describing a method of controlling a threshold voltage of a MOS transistor.

As illustrated in FIG. 1, a photoelectric conversion apparatus 100 according to the present embodiment includes a pixel section 10, a vertical scanning circuit unit 40, a readout circuit unit 50, a horizontal scanning circuit unit 60, an output circuit unit 70, and a control pulse generation unit 80.

A plurality of pixels 12 arranged in an array so as to form a plurality of rows and a plurality of columns are provided in the pixel section 10. As will be described below, each of the pixels 12 may be constituted by a photoelectric conversion unit including a photon sensing element and a pixel signal processing unit configured to process a signal output from the photoelectric conversion unit. It is noted that there is no particular limitation on the number of pixels 12 constituting the pixel section 10. For example, the pixel section 10 may be constituted by a plurality of pixels 12 arranged in an array of several thousand rows×several thousand columns as in a general digital camera. Alternatively, the pixel section 10 may be constituted by a plurality of pixels 12 lined up in a single row or a single column. Alternatively, a single pixel 12 may constitute the pixel section 10.

A control line 14 which extends in a first direction (transverse direction in FIG. 1) is arranged in each row of the pixel array in the pixel section 10. The control line 14 is connected to each of the plurality of pixels 12 lined up in the first direction and serves as a common signal line for these pixels 12. The first direction in which the control line 14 extends may be referred to as a row direction or a horizontal direction. Each of the control lines 14 may include a plurality of signal lines for supplying multiple types of control signals to the pixels 12. The control line 14 in each row is connected to the vertical scanning circuit unit 40.

In addition, a data line 16 which extends in the first direction is arranged in each row of the pixel array in the pixel section 10. The data line 16 is connected to each of the plurality of pixels 12 lined up in the first direction and serves as a common signal line for these pixels 12. Each of the data lines 16 may include a plurality of signal lines for transferring, bit by bit, a multi-bit digital signal output from the pixel 12.

The data line 16 in each row is connected to the readout circuit unit 50.

A control line 18 which extends in a second direction (lengthwise direction in FIG. 1) which intersects with the first direction is arranged in each column of the pixel array in the pixel section 10. The control line 18 is connected to each of the plurality of pixels 12 lined up in the second direction and serves as a common signal line for these pixels 12. The second direction in which the control line 18 extends may be referred to as a column direction or a vertical direction. Each of the control lines 18 may include a plurality of signal lines for supplying multiple types of control signals to the pixel 12. The control line 18 in each column is connected to the horizontal scanning circuit unit 60.

The vertical scanning circuit unit 40 is a control unit having a function of generating, in response to a control signal output from the control pulse generation unit 80, a control signal for driving the pixels 12 and supplying the control signal to the pixels 12 via the control line 14. A logic circuit such as a shift register and an address decoder may be used as the vertical scanning circuit unit 40. The vertical scanning circuit unit 40 sequentially supplies the control signal to the pixels 12 in the pixel section 10 row by row and sequentially drives the pixels 12 in the pixel section 10 row by row.

The horizontal scanning circuit unit 60 is a control unit having a function of generating, in response to a control signal output from the control pulse generation unit 80, a control signal for driving the pixels 12 and supplying the control signal to the pixels 12 via the control line 18. A logic circuit such as a shift register and an address decoder may be used as the horizontal scanning circuit unit 60. The horizontal scanning circuit unit 60 sequentially scans the pixels 12 in the pixel section 10 column by column and outputs a pixel signal held in each of the pixels 12 to the readout circuit unit 50 via the data line 16.

The readout circuit unit 50 includes a plurality of determination circuits and a plurality of holding units (which are not illustrated in the drawing) provided so as to correspond to each row of the pixel array in the pixel section 10. The readout circuit unit 50 has a function of holding the pixel signals of the pixels 12 in each column which are output via the data line 16 from the pixel section 10 row by row in the holding unit in the corresponding column. In response to a control signal supplied via a control line 58 from the control pulse generation unit 80, the readout circuit unit 50 sequentially outputs the pixel signals held in the holding unit in each row to the output circuit unit 70.

The output circuit unit 70 is a circuit unit which includes an external interface circuit and which is configured to output the pixel signals, which have been output from the readout circuit unit 50, to the outside of the photoelectric conversion apparatus 100. There is no particular limitation on the external interface circuit included in the output circuit unit 70. For example, a low voltage differential signaling (LVDS) circuit or a scalable low voltage signaling (SLVS) circuit may be used as the external interface circuit. Any serializer/deserializer (SerDes) transmission circuit is applicable.

The control pulse generation unit 80 is a control circuit configured to generate a control signal for controlling an operation of each of functional blocks of the vertical scanning circuit unit 40, the readout circuit unit 50, and the horizontal scanning circuit unit 60 and timing thereof and supply the generated control signal to the corresponding functional blocks 40, 50, and 60. It is noted that at least some of control signals for controlling the operations and timing of the vertical scanning circuit unit 40, the readout circuit unit 50, and the horizontal scanning circuit unit 60 may be supplied from the outside of the photoelectric conversion apparatus 100. In addition, the control pulse generation unit 80 is also a type of function blocks.

It is noted that a connection mode of each functional block of the photoelectric conversion apparatus 100 is not limited to the configuration example of FIG. 1 and can also be configured as illustrated in FIG. 2, for example.

In the configuration example of FIG. 2, the data line 16 which extends in the second direction is arranged in each column of the pixel array in the pixel section 10. The data line 16 is connected to each of the pixels 12 lined up in the second direction and serves as a common signal line for these pixels 12. The data line 16 in each column is connected to the readout circuit unit 50.

The readout circuit unit 50 is a reception circuit configured to receive a pixel signal output via the data line 16 and has a function of holding the pixel signals of the pixels 12 in each column output via the data line 16 from the pixel section 10 row by row in the holding unit in the corresponding row. The readout circuit unit 50 includes a plurality of determination circuits and a plurality of holding units (not illustrated) provided so as to correspond to each column of the pixel array in the pixel section 10.

The horizontal scanning circuit unit 60 generates, in response to a control signal output from the control pulse generation unit 80, a control for reading out the pixel signals from the holding unit in each column of the readout circuit unit 50. The horizontal scanning circuit unit 60 sequentially scans the holding unit in each column of the readout circuit unit 50 based on the generated control signal and sequentially outputs the pixel signals held in each of the holding units to the output circuit unit 70.

Functions of other functional blocks in the configuration example of FIG. 2 may be similar to functional blocks corresponding to the configuration example of FIG. 1.

As illustrated in FIG. 3, each of the pixels 12 includes a photoelectric conversion unit 20 and a pixel signal processing unit 30. The photoelectric conversion unit 20 includes a photon sensing element 22 and a quench element 24. The pixel signal processing unit 30 includes a waveform shaping circuit 32, a processing circuit 34, and a pixel output circuit 36.

The photon sensing element 22 may be an avalanche diode (hereinafter, referred to as an “APD”). An anode of the APD which constitutes the photon sensing element 22 is connected to a node to which a voltage VL is to be supplied. A cathode of the APD which constitutes the photon sensing element 22 is connected to one terminal of the quench element 24. A connection node between the photon sensing element 22 and the quench element 24 is an output node of the photoelectric conversion unit 20. The other terminal of the quench element 24 is connected to a node to which a voltage VH that is higher than the voltage VL is to be supplied. The voltage VL and the voltage VH are set such that a reverse bias voltage sufficient for the APD to perform the avalanche multiplication operation is applied. In an example, a negative high voltage is supplied as the voltage VL, and a positive voltage at a power source voltage level is supplied as the voltage VH. For example, the voltage VL is −30 V, and the voltage VH is 1 V.

When the APD which constitutes the photon sensing element 22 is supplied with a reverse bias voltage sufficient for the APD to perform the avalanche multiplication operation, charges generated due to the photon incidence on the APD cause an avalanche multiplication to generate an avalanche current. Operation modes in a state in which the APD has been supplied with the reverse bias voltage include a Geiger mode and a linear mode. The Geiger mode is an operation mode in which a voltage applied between the anode and the cathode is set as a reverse bias voltage higher than a breakdown voltage of the APD. The linear mode is an operation mode in which the voltage applied between the anode and the cathode is set as a reverse bias voltage that is around, or less than or equal to, the breakdown voltage of the APD. The APD caused to operate in the Geiger mode is called a single photon avalanche diode (SPAD). The APD which constitutes the photon sensing element 22 may be caused to operate in the linear mode or operate in the Geiger mode.

The quench element 24 has a function of converting a change in the avalanche current generated in the photon sensing element 22 into a voltage signal. In addition, the quench element 24 functions as a load circuit (quench circuit) at the time of signal multiplication based on the avalanche multiplication and has a function of reducing a voltage to be applied to the photon sensing element 22 to suppress the avalanche multiplication. An operation for the quench element 24 to suppress the avalanche multiplication is called a quench operation. In addition, the quench element 24 has a function of restoring the voltage to be supplied to the photon sensing element 22 to the voltage VH by causing a current corresponding to a voltage drop caused by the quench operation to flow. An operation for the quench element 24 to restore the voltage to be supplied to the photon sensing element 22 to the voltage VH is called a recharge operation. The quench element 24 may be constituted by a resistive element, a MOS transistor, or the like.

The waveform shaping circuit 32 includes an input node to which an output signal of the photoelectric conversion unit 20 is to be supplied and an output node. The waveform shaping circuit 32 has a function of converting an analog signal supplied from the photoelectric conversion unit 20 into a pulse signal. The waveform shaping circuit 32 may be constituted by a logical circuit including a NOT circuit (inverter circuit), a NOR circuit, a NAND circuit, or the like. The output node of the waveform shaping circuit 32 is connected to the processing circuit 34.

The processing circuit 34 may include an input node to which an output signal of the waveform shaping circuit 32 is to be supplied, an input node connected to the control line 14, and an output node. The processing circuit 34 is a functional block for performing predetermined processing on the pulse signal output from the waveform shaping circuit 32, and a counter is exemplified as the processing circuit, for example. In a case where the processing circuit 34 is a counter, the processing circuit 34 has a function of counting pulse signals output from the waveform shaping circuit 32 and holding a count value that serves as a count result. A signal supplied from the vertical scanning circuit unit 40 to the processing circuit 34 via the control line 14 includes an enable signal for controlling a counting period (exposure period) of the pulse signals, a reset signal for resetting the count value held by the processing circuit 34, or the like. The output node of the processing circuit 34 is connected to the data line 16 via the pixel output circuit 36.

The pixel output circuit 36 has a function of switching an electric connection state (connected or unconnected) between the processing circuit 34 and the data line 16. The pixel output circuit 36 switches the connection state between the processing circuit 34 and the data line 16 according to the control signal supplied from the horizontal scanning circuit unit 60 via the control line 18 (in the configuration example of FIG. 2, the control signal supplied from the vertical scanning circuit unit 40 via the control line 14). The pixel output circuit 36 may include a buffer circuit configured to output a signal.

The pixel 12 is typically a unit structure configured to output a pixel signal for forming an image. It is however noted in a case where the pixel is used for a purpose of distance measurement or the like using a time of flight (TOF) method, the pixel 12 does not necessarily need to be the unit structure configured to output the pixel signal for forming the image. That is, the pixel 12 may be a unit structure configured to output a signal for measuring a time instant at which light has reached and a light quantity.

It is noted that the pixel signal processing unit 30 does not necessarily need to be provided one by one in each of the pixels 12, and the single pixel signal processing unit 30 may be provided in the plurality of pixels 12.

In this case, it is possible to sequentially execute signal processing of the plurality of pixels 12 by using the single pixel signal processing unit 30.

The photoelectric conversion apparatus according to the present embodiment 100 may be formed on a single substrate or may be constituted as a photoelectric conversion apparatus of a lamination type in which a plurality of substrates are laminated to each other. In the latter case, for example, as illustrated in FIG. 4, it is possible to constitute a photoelectric conversion apparatus of a lamination type in which a first substrate (sensor substrate 110) and a second substrate (circuit substrate 120) are laminated and electrically connected to each other. At least the photon sensing element 22 among the components of the pixel 12 can be arranged on the sensor substrate 110. In addition, the quench element 24 and the pixel signal processing unit 30 among the components of the pixel 12 can be arranged on the circuit substrate 120. The photon sensing element 22 and the quench element 24 and the pixel signal processing unit 30 is electrically connected to each other via a connection wiring provided for each of the pixels 12. In addition, the vertical scanning circuit unit 40, the readout circuit unit 50, the horizontal scanning circuit unit 60, the output circuit unit 70, the control pulse generation unit 80, and the like can be further arranged on the circuit substrate 120.

The photon sensing element 22 and the quench element 24 and the pixel signal processing unit 30 in each of the pixels 12 are provided on the sensor substrate 110 and the circuit substrate 120 so as to be overlapped with each other in plan view. The vertical scanning circuit unit 40, the readout circuit unit 50, the horizontal scanning circuit unit 60, the output circuit unit 70, and the control pulse generation unit 80 can be arranged in a surrounding of the pixel section 10 which is constituted by the plurality of pixels 12.

It is noted that the “plan view” in the present specification refers to viewing from a direction perpendicular to a light incidence plane of the sensor substrate 110.

By constituting the photoelectric conversion apparatus 100 of the lamination type, it is possible to increase an integration density of the elements and achieve a higher functionality. In particular, by arranging the photon sensing element 22 on one substrate and arranging the quench element 24 and the pixel signal processing unit 30 on another substrate, it is possible to arrange the photon sensing elements 22 at a high density without sacrificing a size of a light receiving area of the photon sensing element 22, and a photon sensing efficiency can be improved.

It is noted that the number of substrates which constitute the photoelectric conversion apparatus 100 is not limited to two, and the photoelectric conversion apparatus 100 may be constituted by laminating three or more substrates on one another.

In addition, in FIG. 4, the sensor substrate 110 and the circuit substrate 120 are assumed to be diced chips, but the sensor substrate 110 and the circuit substrate 120 are not limited to the chips. For example, each of the sensor substrate 110 and the circuit substrate 120 may be a wafer. In addition, the sensor substrate 110 and the circuit substrate 120 may be laminated to each other in a wafer state and thereafter diced, or each of the substrates may be chipped and thereafter laminated and bonded to each other.

According to the present embodiment, a configuration using a counter circuit 211 is illustrated. However, the photoelectric conversion apparatus 100 configured to acquire pulse detection timing by using a time to digital converter (hereinafter, TDC) and a memory instead of the counter circuit 211. At this time, generation timing of the pulse signal output from the waveform shaping circuit 32 is converted into a digital signal by the TDC. For measurement of the timing of the pulse signal, the TDC is supplied with a control pulse pREF (reference signal) via a drive line from the vertical scanning circuit unit 40 in FIG. 1. The TDC uses the control pulse pREF as a reference and acquires, as a digital signal, a value at a time when input timing of the signal output from each of the pixels is set as a relative time.

FIGS. 5A to 5C are explanatory diagrams for describing basic operations of the photoelectric conversion unit 20 and the waveform shaping circuit 32. FIG. 5A is a circuit diagram of the photoelectric conversion unit 20 and the waveform shaping circuit 32, FIG. 5B illustrates a waveform of a signal at a node A serving as an input node of the waveform shaping circuit 32, and FIG. 5C illustrates a waveform of a signal at a node B serving as the output node of the waveform shaping circuit 32.

At a time instant t0, a reverse bias voltage of a potential difference equivalent to (VH−VL) is applied to the photon sensing element 22. A reverse bias voltage sufficient to cause the avalanche multiplication is applied between the anode and the cathode of the APD which constitutes the photon sensing element 22, but carriers serving as seeds of the avalanche multiplication do not exist in a state in which a photon is not incident on the photon sensing element 22. For this reason, the avalanche multiplication is not caused in the photon sensing element 22, and a current does not flow in the photon sensing element 22.

At a subsequent time instant t1, it is assumed that a photon is incident on the photon sensing element 22.

When the photon is incident on the photon sensing element 22, electron-hole pairs are created by photoelectric conversion, and the avalanche multiplication is caused using these carriers as the seeds, so that an avalanche multiplication current flows in the photon sensing element 22. When this avalanche multiplication current flows in the quench element 24, a voltage drop occurs due to the quench element 24, and the voltage at the node A begins to drop. As an amount of voltage drop at the node A increases, and when the avalanche multiplication stops at a time instant t3, the voltage level at the node A does not drop any further.

When the avalanche multiplication in the photon sensing element 22 stops, a current for compensating the voltage drop flows at the node A via the photon sensing element 22 from the node to which the voltage VL is to be supplied, and the voltage at the node A gradually increases. Thereafter, the node A settles to its original voltage level at a time instant t5.

The waveform shaping circuit 32 binarizes the signal input from the node A according to a predetermined determination threshold to output a result from the node B. Specifically, the waveform shaping circuit 32 outputs a signal at a low level from the node B when the voltage level at the node A exceeds the determination threshold and outputs a signal at a high level from the node B when the voltage level at the node A is less than or equal to the determination threshold. For example, as illustrated in FIG. 5B, the voltage at the node A is set to be less than or equal to the determination threshold during a period from a time instant t2 to a time instant t4. In this case, as illustrated in FIG. 5C, a signal level at the node B is set to the low level during a period from the time instant t to the time instant t2 and a period from the time instant t4 to the time instant t5 and set to the high level during the period from the time instant t2 to the time instant t4.

In this manner, the analog signal input from the node A is subjected to the waveform shaping into the digital signal by the waveform shaping circuit 32. The pulse signal output from the waveform shaping circuit 32 according to the incidence of the photon on the photon sensing element 22 as described above is a photon sensing pulse signal.

In a case where the processing circuit 34 constitutes a counter, the processing circuit 34 counts the photon sensing pulse signals output from the waveform shaping circuit 32 as described above to hold a count value as a digital signal. The pixel output circuit 36 outputs the digital signal (pixel signal) held by processing circuit 34 to the data line 16 according to the control signal supplied from the horizontal scanning circuit unit 60 via the control line 18.

FIG. 6 illustrates an outline of connection between the pixel section 10 and an image signal output section 90.

The plurality of pixels 12 (PIX UNITs) are arranged in a plurality of rows and a plurality of columns in the pixel section 10 as described above. FIG. 6 illustrates an internal circuit with regard to only the upper left pixel 12 for simplicity of the drawing, but the other pixels 12 also have a similar internal circuit. The data line 16 which extends in the row direction is provided in each row of the pixel array. It is noted that FIG. 6 illustrates a single signal line in each row as the data line 16, but the pixel signal output from the pixel 12 is a digital signal, and the data line 16 in each row includes a plurality of signal lines corresponding to the number of bits of the pixel signal.

The image signal output section 90 is a data output unit including the output circuit unit 70. The image signal output section 90 is configured to meet low-voltage differential signaling (LVDS) or mobile industry processor interface (MIPI: registered trademark). The image signal output section 90 includes a low speed operation circuit 91 (first circuit) and a high speed operation circuit 92 (second circuit) with an operation speed faster than that of the low speed operation circuit 91. The low speed operation circuit 91 is, for example, a circuit configured to perform parallel processing on pixel output signals output from the pixel section 10, such as a decision feedback equalizer (DFE). On the other hand, the high speed operation circuit 92 is a serializer or the like configured to convert the pixel output signals after the parallel processing (parallel data) into serial signals (serial data).

Each of the low speed operation circuit 91 and the high speed operation circuit 92 is constituted by a MOS transistor. Here, characteristics appropriate to the MOS transistor which constitutes each of the low speed operation circuit 91 and the high speed operation circuit 92 will be described.

Examples of typical characteristics demanded for the MOS transistor include a low off-leak current and a high drive force. The off-leak current (also referred to as a subthreshold leak current) refers to a current flowing between a source and a drain in a voltage region (subthreshold region) in which a gate voltage of the MOS transistor is below a threshold voltage. The low off-leak current means a low standby current, which may contribute to reduction in the power consumption. The high drive force means a low on-resistance and a high on-current, which may contribute to high speed operations.

However, these characteristics are in a trade-off relationship, and it is difficult to achieve both characteristics. For example, one of parameters related to the off-leak current and the drive force is a threshold voltage of the transistor. When the threshold voltage is reduced, the drive force can be improved, but the off-leak current increases. On the other hand, when the threshold voltage is increased, the off-leak current can be reduced, but the drive force decreases. Therefore, in one embodiment, a transistor which constitutes a circuit of each unit in the photoelectric conversion apparatus 100 is designed by focusing on a particularly important characteristic demanded for each of the circuits.

Herein, in the photoelectric conversion apparatus according to the present embodiment, a common first power source voltage VDD is supplied to the image signal output section 90 and each of the pixels 12. As described above, the avalanche multiplication is caused in the avalanche photodiode according to the incidence of the photon, and a photon signal is detected since the avalanche current flows. According to the present embodiment, VDD is supplied to one terminal of the APD, and VPDL is supplied to the other terminal, so that a reverse bias voltage sufficient to cause the avalanche multiplication is applied to the APD. In a high illumination environment in particular, the avalanche current may flow in all the pixels in the pixel section at once, and a large current instantaneously may flow to cause a power source fluctuation. This power source fluctuation propagates to the image signal output section 90 through a supply wiring of the first power source voltage VDD, and the operation in the image signal output section 90 may become unstable, or a signal quality may be degraded.

It is common to desire that a microprocess MOS transistor with a high integration density is to set have an off-leak current lowered. However, in a case where the MOS transistor with the low off-leak current is adopted to reduce the off-leak current of the image signal output section 90 configured through a finer process than that for the pixel section 10, the configuration may be more susceptible to the power source fluctuation along with the generation of the avalanche current.

In view of the above, in the photoelectric conversion apparatus according to the present embodiment, a circuit in a part of the image signal output section 90 is constituted by a MOS transistor with a large off-leak current, and the other part (circuit in another part) is constituted by a normal MOS transistor with an off-leak current lower than that of the circuit in the above-described part.

According to this, it is possible to realize the higher functionality and the lower power consumption of the photoelectric conversion apparatus. Specifically, the low speed operation circuit 91 is constituted by the MOS transistor (first transistor) with the low off-leak current, and the high speed operation circuit 92 is constituted by the MOS transistor (second transistor) with the off-leak current higher than that of the first transistor.

In the low speed operation circuit 91 configured to operate at a 100 MHz or lower, an increase in the integration density is demanded from a viewpoint of reduction in a circuit scale, but the drive force is not demanded. Therefore, from a viewpoint of reduction in the power consumption, in one embodiment, the transistor constituting the low speed operation circuit 91 has the off-leak current lower than that of the transistor constituting the high speed operation circuit 92. In other words, an absolute value of the threshold voltage of the transistor which constitutes the low speed operation circuit 91 is larger than an absolute value of the threshold voltage of the transistor which constitutes the high speed operation circuit 92.

Since the high speed operation circuit 92 is configured to operate at a high speed above several hundred MHz (for example, 500 MHz or higher), the circuit is susceptible to power source noise, and the drive force is demanded. Therefore, in one embodiment, the absolute value of the threshold voltage of the transistor which constitutes the high speed operation circuit 92 is lower than the absolute value of the threshold voltage of the transistor which constitutes the low speed operation circuit 91.

FIG. 7A is a schematic diagram illustrating a configuration example of the MOS transistor (first transistor) which constitutes the low speed operation circuit. FIG. 7B to FIG. 7F are schematic diagrams illustrating a configuration example of the MOS transistor (second transistor) which constitutes the high speed operation circuit configured to operate at a higher speed than that of the first transistor.

Each of the MOS transistors illustrated in FIG. 7A to FIG. 7F includes source/drain regions 132, extension regions 134 (or LDD regions 134), and a channel dope layer 136 which are provided to a front surface section of a well 130. In addition, each of the MOS transistors includes a gate insulating film 138 provided above the well 130 and a gate electrode 140 provided above the gate insulating film 138. It is noted that the well 130 has a conductivity type opposite to a conductivity type of the MOS transistor. That is, an N-type MOS transistor is formed for the P-type well 130, and a P-type MOS transistor is formed for the N-type well 130. Furthermore, the channel dope layer 136 is a region doped with an impurity having the same conductivity type as the conductivity type of the MOS transistor. That is, the channel dope layer 136 is a region doped with an N-type impurity in the case of the N-type MOS transistor and is a region doped with a P-type impurity in the case of the P-type MOS transistor. Alternatively, the channel dope layer may be doped with an impurity having a conductivity type opposite to the conductivity type of the MOS transistor. That is, the channel dope layer 136 may be a region doped with a P-type impurity in the case of the N-type MOS transistor and may be a region doped with an N-type impurity in the case of the P-type MOS transistor. The LDD region is a spacer that separates the source/drain regions 132 and the channel dope layer 136 from each other, and since the LDD region is formed, the extension regions and the gate are not overlapped with each other in plan view. According to this, electric field concentration in the vicinity of the source/drain regions 132 is suppressed, and reliability is improved.

At this time, as a concentration of an impurity of the channel dope layer 136 which has the same conductivity type as the conductivity type of the MOS transistor is higher, the threshold voltage is lower. As a concentration of an impurity of the channel dope layer 136 which has a conductivity type opposite to the conductivity type of the MOS transistor in the channel dope layer 136 is lower, the threshold voltage is lower. It is noted that in FIG. 7B to FIG. 7F, each of the MOS transistors includes the extension regions 134 and the channel dope layer 136, but these components are not essential. For example, in a MOS transistor which does not include the extension region 134 or the channel dope layer 136, the threshold voltage may be changed by changing a thickness of an insulating film.

In the MOS transistor illustrated in FIG. 7B, the gate insulating film 138 is set to be thicker than that of the MOS transistor in FIG. 7A. Other aspects are similar to those of the MOS transistor in FIG. 7A.

In the MOS transistor illustrated in FIG. 7C, a gate length is set to be longer than that of the MOS transistor in FIG. 7A. That is, the first transistor has a first channel length, and the second transistor has a second channel length that is longer than the first channel length. Other aspects are similar to those of the MOS transistor in FIG. 7A.

In the extension region 134 of the MOS transistor illustrated in FIG. 7D, a concentration of an impurity having the same conductivity type as the conductivity type of the MOS transistor is set to be lower than that of the MOS transistor in FIG. 7A. That is, in the first transistor, an impurity concentration in a source/drain end portion is a first concentration, and in the second transistor, an impurity concentration in a source/drain end portion is a second concentration that is higher than the first concentration. Other aspects are similar to those of the MOS transistor in FIG. 7A.

In the MOS transistor illustrated in FIG. 7E, an impurity concentration (impurity concentration of the channel dope layer 136) in the channel region of an impurity having the same conductivity type as the conductivity type of the MOS transistor is set to be lower as compared with the case of the MOS transistor in FIG. 7A. Alternatively, an impurity concentration in the channel region of an impurity having a conductivity type opposite to the conductivity type of the MOS transistor is set to be higher as compared with the case of the MOS transistor in FIG. 7A. That is, an impurity concentration in the channel region of the first transistor is a third concentration, and an impurity concentration in the channel region of the second transistor is a fourth concentration that is higher than the third concentration. Other aspects are similar to those of the MOS transistor in FIG. 7A.

In the MOS transistor illustrated in FIG. 7F, halo implantation layers 142 having a conductivity type opposite to that of the source/drain regions 132 and the extension regions 134 are provided in sections deeper than the extension region 134 in the MOS transistor in FIG. 7A. Other aspects are similar to those of the MOS transistor in FIG. 7A.

In any of the structures illustrated in FIG. 7B to FIG. 7F, the threshold voltage of the MOS transistor is lower than that of the MOS transistor in FIG. 7A. By constituting the high speed operation circuit 92 with such a MOS transistor and constituting the low speed operation circuit 91 with the MOS transistor in FIG. 7A, it is possible to realize the lower power consumption in the photoelectric conversion apparatus with the higher functionality through the higher integration density of the circuit. The photoelectric conversion apparatus of each of the following embodiments also attains similar advantages.

### Second Embodiment

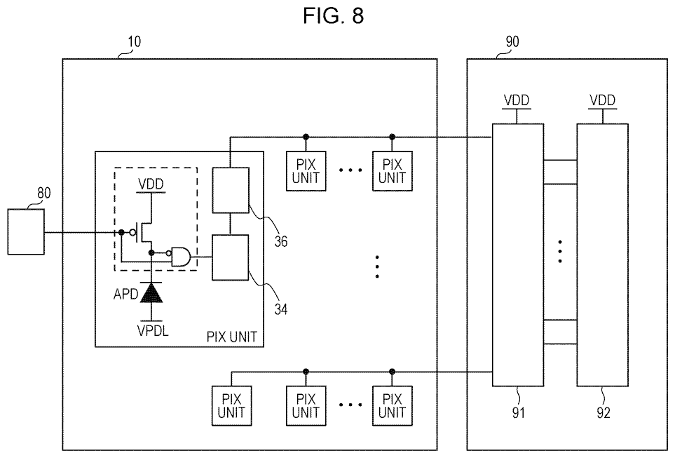

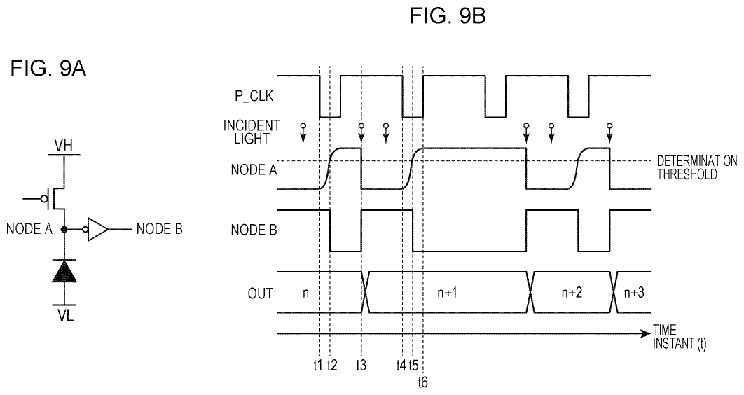

The photoelectric conversion apparatus according to a second embodiment of the disclosure will be described with reference to FIG. 8 and FIGS. 9A and 9B. The same reference numeral is allocated to a component similar to the photoelectric conversion apparatus according to the first embodiment, and the description will be omitted or simplified.

FIG. 8 illustrates an outline of the connection between the pixel section 10 and the image signal output section 90 in the photoelectric conversion apparatus according to the present embodiment. FIG. 8 illustrates an internal circuit with regard to only an internal circuit of the pixel 12 arranged in the upper left pixel section 10 similarly as in FIG. 6. In each of the pixels 12 constituting the pixel section 10 in FIG. 8, since a clock signal is input to the switch which serves as the quench element 24 connected to the photon sensing element 22 as the control signal, clock recharge drive is carried out.

FIG. 9A schematically illustrates a relationship among a control signal P_CLK of a switch serving as the quench element 24 (hereinafter, referred to as a “switch”), a potential at the node A, a potential at the node B, and an output signal. The control signal P_CLK generated by a clock signal generation circuit is input to the quench element 24. According to the present embodiment, in a case where the control signal P_CLK is at the high level, a state is established in which the drive voltage VH (VDD in the present embodiment) is hardly supplied to the photon sensing element 22, and in a case where the control signal P_CLK is at the low level, a state is established in which the drive voltage VH is supplied to the APD. The control signal P_CLK at the high level is, for example, 1 V, and the control signal P_CLK at the low level is, for example, 0 V. The switch turns off in a case where the control signal P_CLK is at the high level, and the switch turns on in a case where the control signal P_CLK is at the low level. A resistance value of the switch in a case where the control signal P_CLK is at the high level is higher than a resistance value of the switch in a case where the control signal P_CLK is at the low level. In a case where the control signal P_CLK is at the high level, since the recharge operation is hardly carried out even when the avalanche multiplication occurs in the APD, a potential to be supplied to the photon sensing element 22 turns to a potential less than or equal to the breakdown voltage of the photon sensing element 22. Therefore, the avalanche multiplication operation in the photon sensing element 22 stops.

As illustrated in FIG. 9A, the switch is constituted by a single transistor to perform the quench operation and the recharge operation by the single transistor. According to this, it is possible to reduce the number of circuits as compared with a case where the quench operation and the recharge operation are respectively performed by different circuit elements. In particular, in a case where each of the pixels has a counter circuit to read out a signal for each of the pixels, a circuit area used for the switch is set to be small since the counter circuit is arranged, and an advantage attained from the switch constituted by the single transistor becomes remarkable.

FIG. 9B illustrates a timing chart in a case where the clock recharge drive has been carried out.

At the time instant t1, the control signal P_CLK changes from the high level to the low level, and the switch turns on to start the recharge operation of the photon sensing element 22. According to this, the potential at the cathode of the photon sensing element 22 transitions to the high level. Then, a potential difference between the potentials to be applied to the anode and the cathode of the photon sensing element 22 is put into a state in which the avalanche multiplication can be carried out. The potential at the cathode is the same as that at the node A. Therefore, when the potential at the cathode transitions from the low level to the high level, the potential at the node A becomes greater than or equal to the determination threshold at the time instant t2. At this time, the pulse signal output from the node B is inverted to turn from the high level to the low level. Thereafter, a state is established in which a potential difference of the drive voltage VH—the drive voltage VL is applied to the photon sensing element 22. The control signal P_CLK turns to the high level, and the switch turns off.

Next, at the time instant t3, when a photon is incident on the photon sensing element 22, the avalanche multiplication occurs in the photon sensing element 22, and the voltage at the cathode drops. That is, the voltage at the node A drops. When the amount of voltage drop further increases and the voltage difference to be applied to the photon sensing element 22 decreases, the avalanche multiplication of the photon sensing element 22 stops as in the time instant t2, and the voltage level at the node A no longer drops by a certain value or beyond. When the voltage at the node A becomes lower than the determination threshold in a middle of the drop of the voltage at the node A, a voltage at the node B turns from the low level to the high level. That is, a part in which an output waveform at the node A exceeds the determination threshold is subjected to the waveform shaping by the waveform shaping circuit 32 to be output as a signal at the node B. Then, the signal is counted by the counter circuit, and a count value of a counter signal output from the counter circuit increases by 1 least significant bit (LSB).

A photon is incident on the photon sensing element 22 between the time instant t3 and the time instant t4. However, the switch is in an off state, and a voltage applied to the photon sensing element 22 is not reaching a potential difference in which the avalanche multiplication can be carried out, so that the voltage level at the node A does not exceed the determination threshold.

At the time instant t4, the control signal P_CLK changes from the high level to the low level, and the switch turns on. Along with this, a current for compensating the voltage drop flows at the node A from the drive voltage VH, and the voltage at the node A transitions to its original voltage level. At this time, since the voltage at the node A becomes greater than or equal to the determination threshold at the time instant t5, the pulse signal of the node B is inverted to turn from the high level to the low level.

At a time instant t6, the node A settles to its original voltage level, and the control signal P_CLK turns from the low level to the high level. Therefore, the switch turns off. At a later time too, the potential at each node, signal line, or the like changes according to the control signal P_CLK or photon incidence as described in relation with the time instant t1 to the time instant t6.

It is noted that in the circuit configurations illustrated in FIG. 8 and FIG. 9A, a logical product of the control signal P_CLK and the signal output from the node B is input to the processing circuit 34 by using a logical circuit 38, so that saturation of the counter constituting the processing circuit 34 is avoided.

In a case where the above-described clock recharge drive has been carried out, in an image sensing environment at a high illumination, the recharge operation occurs at once in the plurality of pixels 12 according to an input of the control signal P_CLK. That is, the power source fluctuation is more likely to occur as compared with a case where passive drive is carried out as in the photoelectric conversion apparatus according to the first embodiment, and a risk for the image signal output section 90 to malfunction is also increased. In such a photoelectric conversion apparatus, since the transistors which constitute the image signal output section 90 are fabricated in different manners depending on their functions similarly as in the first embodiment, it is possible to realize the higher functionality and the lower power consumption of the photoelectric conversion apparatus.

In the photoelectric conversion apparatus according to an aspect of the embodiments, the processing circuit 34 in the pixel is also constituted by the MOS transistor with the low off-leak current similarly as in the low speed operation circuit 91. Since the processing circuit 34 is a circuit configured to operate at a low speed and has a relatively large scale, a high threshold voltage Vth is set to be high.

In addition, the pixel output circuit 36 has a function of causing a potential at an output line to converge to one voltage out of the power source voltage and a reference voltage according to the output signal of the processing circuit 34. Herein, the plurality of pixels 12 are connected to the output line according to the number of columns or the number of rows. That is, many MOS transistors are connected to the output line to form a series of large parasitic capacitances. In addition, the output line has a long wiring length and has also a large parasitic resistance. For this reason, the pixel output circuit 36 is demanded to be constituted by the MOS transistor with the high drive force which may drive a signal on a high load wiring. Therefore, in one embodiment, the transistor of the pixel output circuit 36 reduces the threshold voltage Vth to set the threshold voltage to be lower than that of the transistor of the processing circuit 34 to improve the drive force.

Since a voltage higher than a voltage Vdd is applied to the logical circuit 38, the logical circuit 38 is constituted by a transistor with a breakdown voltage higher than those of the transistors constituting the processing circuit 34 and the pixel output circuit 36. The transistor with a high breakdown voltage may be a transistor with a gate insulating film thicker than those of the transistors constituting the processing circuit 34 and the pixel output circuit 36. In a case where the quench element 24 is constituted by a transistor too, similarly as in the logical circuit 38, the quench element 24 is constituted by the transistor with the breakdown voltage higher than those of the transistors constituting the processing circuit 34 and the pixel output circuit 36.

In this manner, according to the present embodiment, it is possible to realize the higher functionality and the lower power consumption of the photoelectric conversion apparatus.

### Third Embodiment

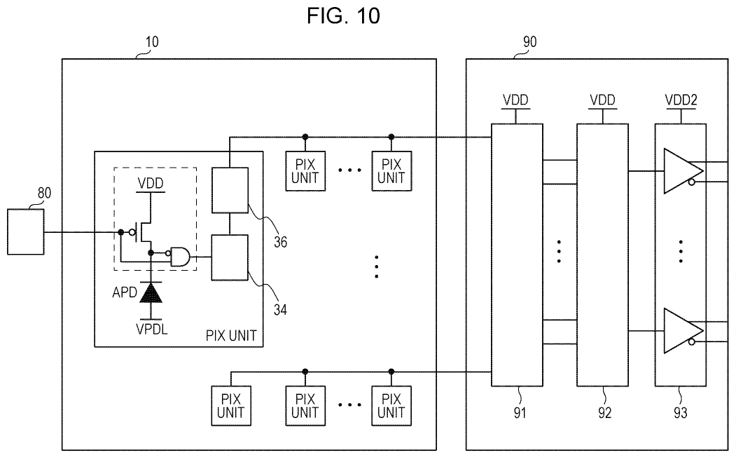

The photoelectric conversion apparatus according to a third embodiment of the disclosure will be described with reference to FIG. 10. The same reference numeral is allocated to a component similar to the photoelectric conversion apparatus according to the first embodiment, and the description will be omitted or simplified.

The image signal output section 90 in the photoelectric conversion apparatus according to the present embodiment further includes a pixel signal output circuit 93. The pixel signal output circuit is, for example, an output unit of a high speed serial interface such as LVDS or MIPI. Since signals are to be output to the outside of the photoelectric conversion apparatus, a second power source voltage VDD2 having an absolute value different from that of the power source voltage VDD for the pixel section 10 and the low speed operation circuit 91 and the high speed operation circuit 92 in the image signal output section 90 is supplied. Herein, VDD2 is an independent power source with little power source noise.

Since the pixel signal output circuit 93 is a circuit configured to operate at a high speed but is driven by VDD2 that is the independent power source, the power source fluctuation along with the generation of the avalanche current is small. For this reason, similarly as in the low speed operation circuit 91, the pixel signal output circuit 93 may be constituted by the MOS transistor (third transistor) with the low leak current.

A configuration of the MOS transistor which constitutes the pixel signal output circuit 93 is common to that in FIG. 7A. That is, an absolute value of the threshold voltage of the third transistor is larger than an absolute value of the threshold voltage of the second transistor. In addition, when an impurity concentration in the channel region of the second transistor is set as a fourth concentration, an impurity concentration in the channel region of the third transistor is a fifth concentration that is lower than the fourth concentration.

Furthermore, similarly as in the second embodiment, an absolute value of the threshold voltage of the transistor (fourth transistor) which constitutes the processing circuit 34 is larger than an absolute value of the threshold voltage of the second transistor. That is, an impurity concentration in the channel region of the fourth transistor is a sixth concentration that is lower than the fourth concentration. In addition, the fourth transistor constituting the processing circuit 34 and the first transistor constituting the low speed operation circuit 91 may be transistors having the threshold voltages absolute values of which are equal to each other.

In this manner, according to the present embodiment, it is possible to realize the higher functionality and the lower power consumption of the photoelectric conversion apparatus.

### Fourth Embodiment

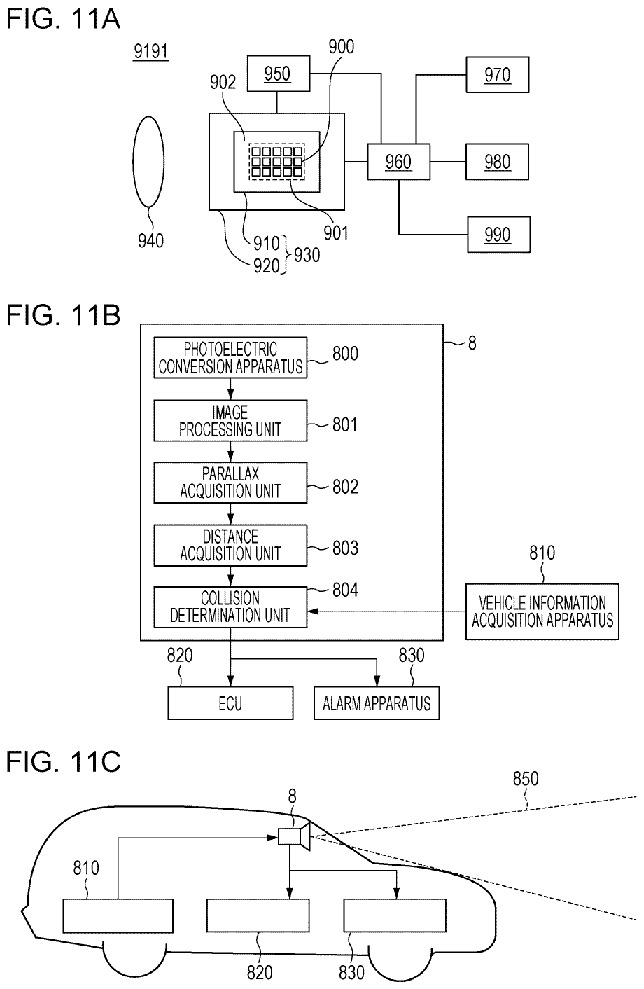

A fourth embodiment can be applied to any of the first embodiment to the third embodiment. FIG. 11A is a schematic diagram for describing an equipment 9191 including a semiconductor apparatus 930 using the photoelectric conversion apparatus of each of the above-mentioned embodiments. The equipment 9191 including the semiconductor apparatus 930 will be described in detail. The semiconductor apparatus 930 can include, in addition to a semiconductor device 910, a package 920 that accommodates the semiconductor device 910. The package 920 can include a base to which the semiconductor device 910 is fixed and a lid such as glass facing the semiconductor device 910. The package 920 can further include a bonding member such as a bonding wire or a bump that connects a terminal provided in the base and a terminal provided in the semiconductor device 910.

The equipment 9191 may include at least any of an optical apparatus 940, a control apparatus 950, a processing apparatus 960, a display apparatus 970, a storage device 980, and a mechanical apparatus 990. The optical apparatus 940 corresponds to the semiconductor apparatus 930. The optical apparatus 940 is, for example, a lens, a shutter, or a mirror and includes an optical system configured to guide light to the semiconductor apparatus 930. The control apparatus 950 controls the semiconductor apparatus 930. The control apparatus 950 is, for example, a semiconductor apparatus such as an application specific integrated circuit (ASIC).

The processing apparatus 960 processes a signal output from the semiconductor apparatus 930. The processing apparatus 960 is a semiconductor apparatus such as a central processing unit (CPU) or an ASIC that constitutes an analog front end (AFE) or a digital front end (DFE). The display apparatus 970 is an electro-luminescence (EL) display apparatus or a liquid crystal apparatus configured to display information (image) acquired by the semiconductor apparatus 930. The storage device 980 is a magnetic device or a semiconductor device configured to store the information (image) acquired by the semiconductor apparatus 930. The storage device 980 is a volatile memory such as a static random access memory (SRAM) or a dynamic random access memory (DRAM), or a non-volatile memory such as a flash memory or a hard disk drive.

The mechanical apparatus 990 includes a movable part or a propulsive part such as a motor or an engine. In the equipment 9191, the signal output from the semiconductor apparatus 930 is displayed on the display apparatus 970 or transmitted to the outside by a communication apparatus (not illustrated) included in the equipment 9191. For this reason, the equipment 9191 may further include the storage device 980 or the processing apparatus 960 in addition to a storage circuit or an arithmetic operation circuit included in the semiconductor apparatus 930. The mechanical apparatus 990 may be controlled based on the signal output from the semiconductor apparatus 930.

The equipment 9191, in one embodiment, is also used as electronic equipment such as an information terminal (for example, a smartphone or a wearable terminal) having a shooting function or a camera (for example, an interchangeable lens camera, a compact camera, a video camera, or a surveillance camera). The mechanical apparatus 990 in the camera can drive parts of the optical apparatus 940 for zooming, focusing, and a shutter operation. Alternatively, the mechanical apparatus 990 in the camera can move the semiconductor apparatus 930 for an image stabilization operation.

The equipment 9191 may be transportation equipment such as a vehicle, a ship, or a flying object. The mechanical apparatus 990 in the transportation equipment may be used as a transportation apparatus. The equipment 9191 serving as the transportation equipment may be used as a component configured to transport the semiconductor apparatus 930 or a component configured to assist and/or automate driving (piloting) by the shooting function. The processing apparatus 960 configured to assist and/or automate driving (piloting) can perform processing to operate the mechanical apparatus 990 serving as the transportation apparatus based on the information acquired by the semiconductor apparatus 930. Alternatively, the equipment 9191 may be medical equipment such as an endoscope, measuring equipment such as a distance measuring sensor, analytical equipment such as an electron microscope, office equipment such as a copier, or industrial equipment such as a robot.

According to the above-described embodiment, it becomes possible to attain a satisfactory pixel characteristic. Therefore, a value of the semiconductor apparatus can be increased. For the increase in the value mentioned herein, at least any of an addition of a function, an improvement of a performance, an improvement of a characteristic, an improvement of a reliability, an improvement of a manufacturing yield, a reduction of an environmental impact, a cost reduction, a size reduction, and a weight reduction applies.

Therefore, when the semiconductor apparatus 930 according to the present embodiment is used as the equipment 9191, the value of the equipment can also be improved. For example, by mounting the semiconductor apparatus 930 to the transportation equipment, it is possible to attain an excellent performance when an outside of the transportation equipment is shot or an external environment is measured. Thus, when the transportation equipment is to be manufactured and to be on sale, a decision of mounting the semiconductor apparatus according to the present embodiment to the transportation equipment is advantageous in an improvement of the performance of the transportation equipment itself. In particular, the semiconductor apparatus 930, in one embodiment, is used as the transportation equipment configured to perform driving assistance and/or automated driving of the transportation equipment by using the information acquired by the above-described semiconductor apparatus.

A photoelectric conversion system of the present embodiment and a moving object of the present embodiment will be described with reference to FIGS. 11B and 11C.

FIG. 11B illustrates an example of a photoelectric conversion system related to an on-vehicle camera. A photoelectric conversion system 8 includes a photoelectric conversion apparatus 800. The photoelectric conversion apparatus 800 is the photoelectric conversion apparatus (image sensing apparatus) described in any of the above-described embodiments. The photoelectric conversion system 8 includes an image processing unit 801 configured to perform image processing on a plurality of pieces of image data acquired by the photoelectric conversion apparatus 800 and a parallax acquisition unit 802 configured to calculate a parallax (phase difference of parallax images) from a plurality of pieces of image data acquired by the photoelectric conversion system 8. The photoelectric conversion system 8 also includes a distance acquisition unit 803 configured to calculate a distance to the target object based on the calculated parallax and a collision determination unit 804 configured to determine whether or not there is a possibility of collision based on the calculated distance. Herein, the parallax acquisition unit 802 and the distance acquisition unit 803 are examples of a distance information acquisition unit configured to acquire distance information of a distance to the target object. That is, the distance information refers to information related to a parallax, a defocus amount, a distance to the target object, or the like. The collision determination unit 804 may determine the possibility of collision by using any of these pieces of distance information. The distance information acquisition unit may be realized by specifically designed hardware or may be realized by a software module. In addition, the distance information acquisition unit may be realized by a field programmable gate array (FPGA), an application specific integrated circuit (ASIC), or the like or may be realized by a combination of these components.

The photoelectric conversion system 8 is connected to a vehicle information acquisition apparatus 810 and can acquire vehicle information such as a vehicle speed, a yaw rate, or a steering angle. The photoelectric conversion system 8 is also connected to a control electronic control unit (ECU) 820 serving as a control apparatus configured to output a control signal for generating a braking force for the vehicle based on a result of the determination in the collision determination unit 804. The photoelectric conversion system 8 is also connected to an alarm apparatus 830 configured to issue an alarm to a driver based on a result of the determination in the collision determination unit 804. For example, in a case where the possibility of collision is high as the determination result of the collision determination unit 804, the ECU 820 performs vehicle control to avoid a collision or mitigate damage by applying a brake, releasing an accelerator, reducing an engine output, or the like. The alarm apparatus 830 warns a user by sounding an alarm such as a sound, displaying alarm information on a screen such as a car navigation system, applying vibration to a seat belt or a steering wheel, or the like.

According to the present embodiment, an image of a surrounding of the vehicle, for example, a front area or a rear area is to be sensed by the photoelectric conversion system 8.

FIG. 11C illustrates the photoelectric conversion system in a case where an image of the front area of the vehicle (image sensing area 850) is to be sensed. The vehicle information acquisition apparatus 810 transmits an instruction to the photoelectric conversion system 8 or the photoelectric conversion apparatus 800. With such a configuration, an accuracy of the distance measurement can be further improved.

In the above, the example of the control to avoid the collision with other vehicles has been described, but the embodiment can be applied to control for autonomous drive by following other vehicles, control for autonomous drive so as not to stray from its lane, or the like. Furthermore, the photoelectric conversion system can be applied to not only a vehicle such as a car but also a moving object (mobile apparatus) such as, for example, a ship, aircraft, or an industrial robot. Moreover, the embodiment can be applied to not only the moving object but also an equipment that widely uses object recognition such as intelligent transport systems (ITS).

The embodiments described above can be modified as appropriate in a scope without departing from the technical concept. It is noted that the content disclosed in the present specification is not limited to described configurations in the present specification but also includes all matters that can be understood from the present specification and the accompanying drawings of the present specification. The content disclosed in the present specification also includes a complement set of concepts described in the present specification. That is, when a phrase “A is larger than B” is stated in the present specification, for example, even when a phrase “A is not larger than B” is omitted, it can be construed that the present specification discloses a notion that “A is not larger than B”. This is because in a case where the phrase “A is larger than B” is stated, it is assumed that a case where “A is not larger than B” is taken into consideration.

While the disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2024-049499 filed Mar. 26, 2024, which is hereby incorporated by reference herein in its entirety.

What is claimed is:

1. A conversion apparatus comprising:
a pixel including an avalanche diode and a circuit configured to process a signal according to an output of the avalanche diode; and
an output unit configured to output data according to an output signal of the pixel, wherein
the output unit includes a first circuit and a second circuit configured to operate at a speed faster than a speed of the first circuit, and
an absolute value of a threshold voltage of a first transistor which constitutes the first circuit is larger than an absolute value of a threshold voltage of a second transistor which constitutes the second circuit.

2. The conversion apparatus according to claim 1, wherein a first voltage is supplied to the second circuit and the pixel.

3. The conversion apparatus according to claim 1, wherein a clock signal is input to a switch provided between the avalanche diode and a node from which a power source to be applied to the avalanche diode is supplied.

4. The conversion apparatus according to claim 1, wherein
in the first transistor, an impurity concentration at a drain end portion of an impurity having a conductivity type that is the same as a conductivity type of the first transistor is a first concentration, and
in the second transistor, an impurity concentration at a drain end portion of an impurity having a conductivity type that is the same as a conductivity type of the second transistor is a second concentration that is higher than the first concentration.

5. The conversion apparatus according to claim 1, wherein
in the first transistor, an impurity concentration in a channel region of an impurity having a conductivity type that is the same as a conductivity type of the first transistor is a third concentration, and
in the second transistor, an impurity concentration in a channel region of an impurity having a conductivity type that is the same as a conductivity type of the second transistor is a fourth concentration that is higher than the third concentration.

6. The conversion apparatus according to claim 1, wherein
the first transistor has a first channel length, and
the second transistor has a second channel length that is longer than the first channel length.

7. The conversion apparatus according to claim 1, wherein a gate insulating film of the first transistor is thicker than a gate insulating film of the second transistor.

8. The conversion apparatus according to claim 1, wherein the second circuit includes a serializer configured to convert parallel data into serial data.

9. The conversion apparatus according to claim 2, wherein
the output unit includes a pixel signal output circuit, and
a second power source voltage having a magnitude different from that of the first power source voltage is supplied to the pixel signal output circuit.

10. The conversion apparatus according to claim 9, wherein an absolute value of a threshold voltage of a third transistor which constitutes the pixel signal output circuit is larger than the absolute value of the threshold voltage of the second transistor.

11. The conversion apparatus according to claim 10, wherein
in the second transistor, an impurity concentration in a channel region of an impurity having a conductivity type that is the same as a conductivity type of the second transistor is a fourth concentration, and
in the third transistor, an impurity concentration in a channel region of an impurity having a conductivity type that is the same as a conductivity type of the third transistor is a fifth concentration that is lower than the fourth concentration.

12. The conversion apparatus according to claim 1, wherein an absolute value of a threshold voltage of a fourth transistor which constitutes the circuit in the pixel is larger than the absolute value of the threshold voltage of the second transistor.

13. The conversion apparatus according to claim 12, wherein
in the second transistor, an impurity concentration in a channel region of an impurity having a conductivity type that is the same as a conductivity type of the second transistor is a fourth concentration, and
in the fourth transistor, an impurity concentration in a channel region of an impurity having a conductivity type that is the same as a conductivity type of the fourth transistor is a sixth concentration that is lower than the fourth concentration.

14. The conversion apparatus according to claim 12, wherein the absolute value of the threshold voltage of the fourth transistor is equal to the absolute value of the threshold voltage of the first transistor.

15. The conversion apparatus according to claim 1, wherein the circuit in the pixel includes a time to digital converter.

16. The conversion apparatus according to claim 1, wherein a first substrate to which the avalanche diode is provided and a second substrate to which the circuit and the output unit are provided are laminated to each other.

17. A system comprising:
the conversion apparatus according to claim 1; and
a processing apparatus configured to process a signal output from the conversion apparatus.

18. A moving object comprising:
the conversion apparatus according to claim 1;
an acquisition unit configured to acquire information of a distance to a target object based on a signal output from the conversion apparatus; and
a control unit configured to control the moving object based on the distance information.

19. An equipment comprising the conversion apparatus according to claim 1, wherein
the equipment further comprises at least any of
an optical apparatus configured to guide light to the conversion apparatus,
a control apparatus configured to control the conversion apparatus,
a processing apparatus configured to process a signal output from the conversion apparatus,
a display apparatus configured to display information acquired in the conversion apparatus,
a storage device configured to store information acquired in the conversion apparatus, and
a mechanical apparatus arranged to operate based on information acquired in the conversion apparatus.
